(19) United States
(12) Patent Application Publication
(10) Pub. No.: US 2016/0258064 A1
(43) Pub. Date: Sep. 8, 2016

(54) BARRIER ANODIZATION METHODS TO DEVELOP ALUMINUM OXIDE LAYER FOR PLASMA EQUIPMENT COMPONENTS

(71) Applicant: Applied Materials, Inc., Santa Clara, CA (US)

(72) Inventors: Yogita PAREEK, Jaipur (IN); Ankur KADAM, Mumbai (IN); Laksheswar KALITA, Mumbai (IN); Bipin THAKUR, Mumbai (IN); Dmitry LUBOMIRSKY, Cupertino, CA (US)

(21) Appl. No.: 14/705,659

(22) Filed: May 6, 2015

(30) Foreign Application Priority Data
Mar. 6, 2015 (IN) 1110/CHE/2015

(51) Int. Cl. C23C 16/50; C25D 11/08; C25D 11/10

(52) U.S. Cl. CPC C23C 16/50; C25D 11/10; C25D 11/08

(57) ABSTRACT

The disclosure relates to a chamber component or a method for fabricating a chamber component for use in a plasma processing chamber apparatus. In one embodiment, a chamber component, for use in a plasma processing apparatus, includes an aluminum body having an anodized coating disposed on the aluminum body formed from a neutral electrolyte solution, wherein the anodized coating has a film density higher than 3.1 g/cm⁻².

### CROSS-REFERENCE TO RELATED APPLICATIONS

This application claims benefit of Indian Provisional Application Serial No. 1110/CHE/2015 filed Mar. 6, 2015 (Attorney Docket No. APPM/22558IN), which is incorporated by reference in its entirety.

### FIELD

Embodiments disclosed herein generally relate to manufacturing a coating/barrier/passivation layer on a processing chamber component resistive to the corrosive plasma environment utilized in a semiconductor plasma processing chamber. More specifically, embodiments disclosed herein relate to form a thickness tunable barrier alumina utilized in plasma equipment components for reduction of particles and stabilization of etch rates in plasma processing equipment in semiconductor tools.

### DESCRIPTION OF THE PRIOR ART

Semiconductor processing involves a number of different chemical and physical processes whereby minute integrated circuits are created on a substrate. Layers of materials which make up the integrated circuit are created by chemical vapor deposition, physical vapor deposition, epitaxial growth, chemical treatment, electrochemical process and the like. Some of the layers of material are patterned using photoresist masks and wet or dry etching techniques. The substrate utilized to form integrated circuits may be silicon, gallium arsenide, indium phosphide, glass, or other appropriate material.

A typical semiconductor processing chamber includes a chamber body defining a process zone, a gas distribution assembly adapted to supply a gas from a gas supply into the process zone, a gas energizer, e.g., a plasma generator, utilized to energize the process gas to process a substrate positioned on a substrate support assembly, and a gas exhaust. During plasma processing, the energized gas is often comprised of ions, radicals and highly reactive species which etches and erodes exposed portions of the processing chamber components, for example, an electrostatic chuck that holds the substrate during processing. Additionally, processing by-products are often deposited on chamber components which must be periodically cleaned typically with highly reactive fluorine. Attack from the reactive species during processing and cleaning reduces the lifespan of the chamber components and increase service frequency. Additionally, flakes from the eroded parts of the chamber component may become a source of particulate contamination during substrate processing. As such, the chamber components must be replaced after a number of process cycles and before they provide inconsistent or undesirable properties during substrate processing. Therefore, promoting plasma resistance of chamber components is desirable to increase service life of the processing chamber, reduce chamber downtime, reduce maintenance frequency, and improve product yields.

Conventionally, the processing chamber surface may include certain coatings to provide a degree of protection from the corrosive processing environment or to promote the surface protection of the chamber components. Several conventional methods utilized to coat the protective layer include physical vapor deposition (PVD), chemical vapor deposition (CVD), sputtering, plasma spraying coating, solution plating process, aerosol deposition (AD), chemical treatment process, electrochemical process and the like. Some conventional coating techniques typically employ a substantially high temperature to provide sufficient thermal energy to sputter, deposit or eject a desired amount of materials on a component surface. However, high temperature processing may deteriorate surface properties or adversely modify the microstructure of the coated surface, resulting in a coated layer having poor uniformity and/or surface cracks due to temperature elevation. Furthermore, some coating techniques cannot be easily adhered on the surface of the components due to complex designed of the holes/special patterns formed in the parts. In contrast, some other conventional coating techniques utilize acid solution to plate a desired amount of material onto the component surface. However, acid solution often attack the materials formed on the component surface, resulting in the coating material overly porous or with loose bonding structure, which may be easily attacked and damaged under a plasma corrosive environment. As a result, the component surface may deteriorate over time and eventually expose the underlying component surface to corrosive plasma attack.

Therefore, there is a need for an improved method for forming chamber components with a robust coating that is more resistive to a processing chamber environment.

### SUMMARY

Embodiments of the disclosure provide a chamber component for use in a plasma processing chamber apparatus. In one embodiment, a chamber component, for use in a plasma processing apparatus, includes an aluminum body having an anodized coating disposed on the aluminum body formed from a neutral electrolyte solution, wherein the anodized coating has a density higher than a film density higher than 3.1 g/cm³.

In another embodiment of the disclosure, an apparatus for use in a plasma processing chamber having a substrate pedestal adapted to support a substrate includes a chamber component having an aluminum body with an anodized coating disposed on the aluminum body formed from a neutral electrolyte solution, wherein the anodized coating has a roughness less than 16 Ra.

In yet embodiment of the disclosure, a method for fabricating a chamber component for use in a plasma processing environment includes immersing a body of the chamber component from aluminum into an electrolyte solution including at least one ammonium salt, controlling a pH level of the electrolyte solution around neutral, applying a voltage to the electrolyte solution, and forming an anodizing coating on the body.

### BRIEF DESCRIPTION OF THE APPENDED DRAWINGS

The teachings of the present disclosure can be readily understood by considering the following detailed description in conjunction with the accompanying drawings, in which:

FIG. 1 illustrates a sectional view of a chamber component having a coating according to one embodiment of the disclosure;

FIG. 2 illustrates a processing chamber which uses the chamber component of FIG. 1;

FIG. 3 depicts a flow diagram of one embodiment of a method for fabricating the chamber component of FIG. 1; and

FIGS. 4A-4B depict different manufacturing stages of a chamber component with the coating of FIG. 1 depicted in FIG. 3.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

According to one embodiment of the disclosure, a chamber component is provided that includes an aluminum body having a electrochemical plating coating with a thickness tunable aluminum oxide which is compact and thicker in nature for use in plasma equipment components. In one example, the coating may be formed from an electrochemical plating process utilizing neutral electrolytes. Process parameters (e.g., voltage or temperature) may be adjusted to form tunable aluminum oxide with desired thickness. Examples of the electrolytes may include ammonium salt including aluminum adipate, ammonium borate and the like that may maintain electrolyte solution having a substantially neutral pH value.

In one embodiment, the coating layer may have a thickness between about 10 nm and about 200 nm. The coating layer maybe formed amorphous in nature. Surface morphology, electrochemical behavior and crystal structure of the coating may be formed in an aqueous ammonium salt solution with a neutral pH value ranging from 5 to 9 with a solution temperature at 10° C. and 100° C. The surface morphology of coating may be inspected by scanning Electron microscope (SEM), transmission electron microscopy (TEM), and Laser Microscopy. Compactness of the coating layer was inspected by detecting the electrochemical behavior of coating layer, density and resistivity was measured in different corrosive environments.

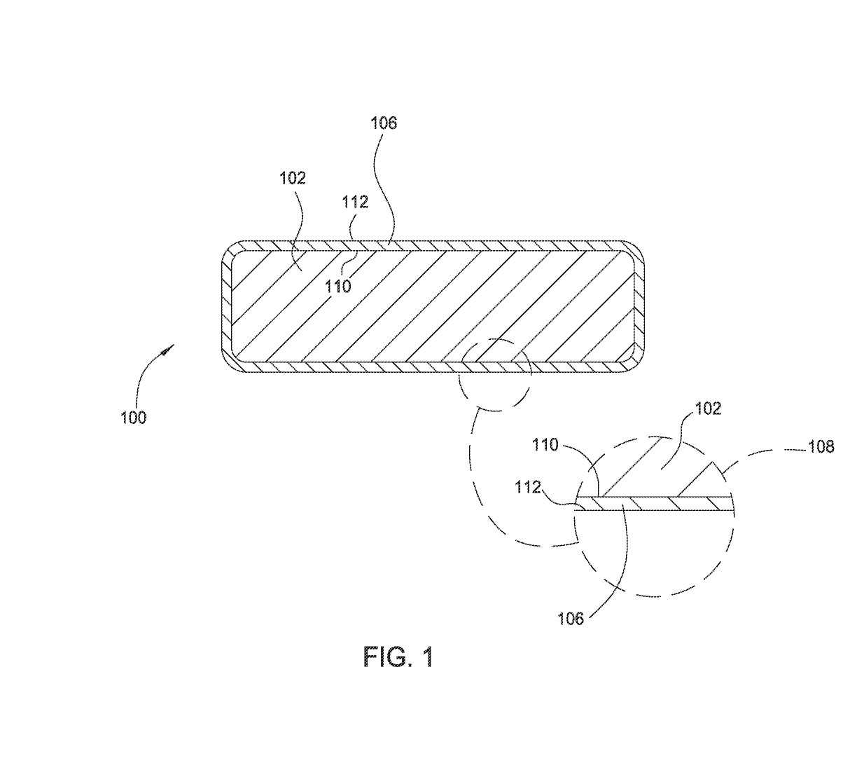

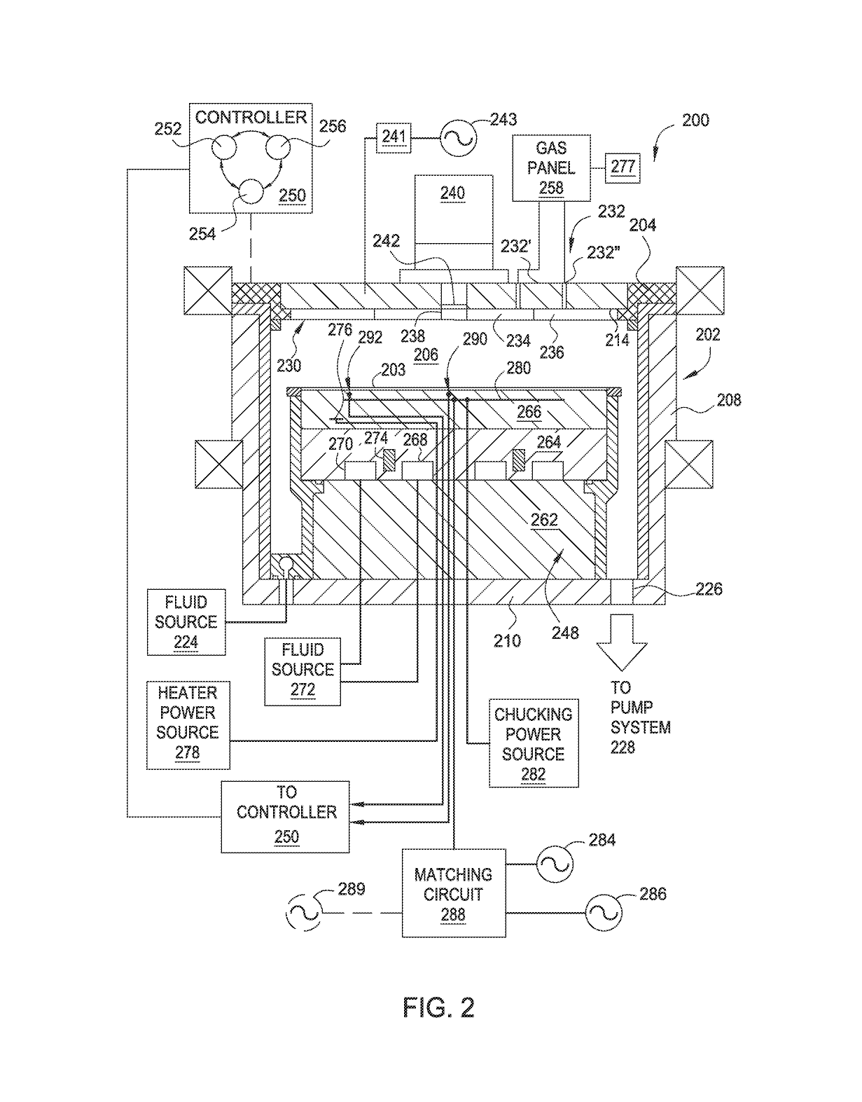

FIG. 1 illustrates a sectional view of one embodiment of a plasma processing chamber component 100 that may be used within a processing chamber, which as a processing chamber 200 of FIG. 2, which will be described in further detail below. Although the chamber component 100 is shown in FIG. 1 as having a rectangular cross-section, for the purposes of discussion it is understood that the chamber component 100 may take the form of any chamber part, including, but not limited to, a chamber body, a chamber body upper liner, a chamber body lower liner, chamber body plasma door, a cathode liner, a chamber lid gas ring, a throttling gate valve spool, a plasma screen, a pedestal, a substrate support assembly, a showerhead, a gas nozzle, and the like.

The chamber component 100 has at least one exposed surface 112 that is exposed to the plasma environment within the processing chamber when in use. The chamber component 100 includes a body 102 having a conformal anodized coating 106 disposed on an outer surface 110 of the body 102.

The anodized coating 106 fills and bridges imperfections along the outer surface 110 of the aluminum body 102 while producing a smooth and crack-free outer surface 110. Since the outer surface 110 on which the anodized coating 106 is formed is substantially defect free, high density and compactness, there are no initiation sites for cracks to form and propagate through the anodized coating 106, resulting in a relatively smooth and defect-free outer surface 112 with minimum porosity.

In one example, the anodized coating 106 covers and encapsulates the aluminum body 102 and forms the outer surface 112 that is exposed to the plasma environment of a processing chamber. The anodized coating 106 generally resists the corrosive elements found within the process volume and protects the chamber component from decay and wear. In one specific embodiment, the anodized coating 106 has a thickness between 0.1 μm and about 1 μm.

FIG. 2 is a sectional view of one example of a processing chamber 200 suitable for performing a plasma process that may utilize corrosive gas species during the plasma process. Suitable processing chambers that may be adapted for use with the teachings disclosed herein include, for example, a FRONTIER®, ENABLER® or C3® processing chamber available from Applied Materials, Inc. of Santa Clara, Calif.

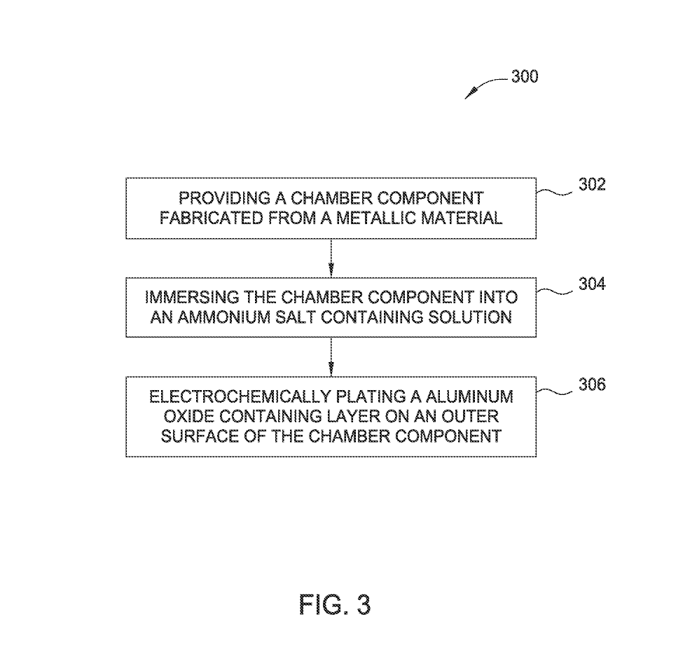

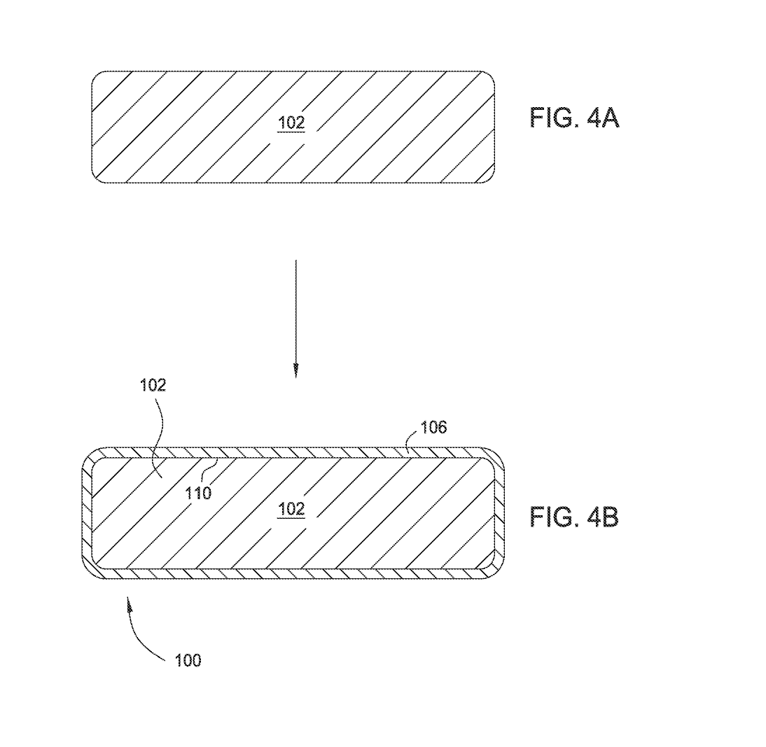

It is noted that various chamber components in the processing chamber 200 described below may be fabricated using the anodization coating process described below with referenced to FIGS. 3 and 4. These chamber components are frequently exposed to the plasma processing environment. For example, the anodized coatings may be applied to a chamber body 202, sidewalls 228 and bottom 210, a showerhead assembly 230 and a pedestal or substrate support pedestal assembly 248, or any suitable chamber components included in the processing chamber 200.

The processing chamber 200 includes a chamber body 202 and a lid 204 which enclose an interior volume 206. The chamber body 202 is typically fabricated from aluminum, stainless steel or other suitable material. The chamber body 202 generally includes sidewalls 208 and a bottom 210. A substrate support pedestal access port (not shown) is generally defined in the sidewall 208 and selectively sealed by a slit valve to facilitate entry and egress of a substrate 203 from the processing chamber 200. An exhaust port 226 is defined in the chamber body 202 and couples the interior volume 206 to a pump system 228. The pump system 228 generally includes one or more pumps and throttle valves utilized to evacuate and regulate the pressure of the interior volume 206 of the processing chamber 200. In one implementation, the pump system 228 maintains the pressure inside the interior volume 206 at operating pressures typically between about 10 mTorr to about 500 Torr.

The lid 204 is sealingly supported on the sidewall 208 of the chamber body 202. The lid 204 may be opened to allow excess to the interior volume 106 of the processing chamber 200. The lid 204 includes a window 242 that facilitates optical process monitoring. In one implementation, the window 242 is comprised of quartz or other suitable material that is transmissive to a signal utilized by an optical monitoring system 240 mounted outside the processing chamber 200.

The optical monitoring system 240 is positioned to view at least one of the interior volume 206 of the chamber body 202 and/or the substrate 100 positioned on a substrate support pedestal assembly 248 through the window 242. In one embodiment, the optical monitoring system 240 is coupled to the lid 204 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

A gas panel 258 is coupled to the processing chamber 200 to provide process and/or cleaning gases to the interior volume 206. In the example depicted in FIG. 2, inlet ports 232′, 232″ are provided in the lid 204 to allow gases to be delivered from the gas panel 258 to the interior volume 206 of the processing chamber 200. In one implementation, the gas panel 258 is adapted to provide fluorinated process gas through the inlet ports 232′, 232″ and into the interior volume 206 of the processing chamber 200. In one implementation, the process gas provided from the gas panel 258 includes at least a fluorinated gas, chlorine, and a carbon containing gas, an oxygen gas, a nitrogen containing gas and a chlorine containing gas. Examples of fluorinated and carbon containing gases include CHF₃, CH₂F₂ and CF₄. Other fluorinated gases may include one or more of C₂F, NF₃, F₂, C₄F₆, C₃F₈ and C₅F₈. Examples of the oxygen containing gas include O₂, CO₂, CO, N₂O, NO₂, O₃, H₂O, and the like. Examples of the nitrogen containing gas include N₂, NH₃, N₂O, NO₂ and the like. Examples of the chlorine containing gas include HCl, Cl₂, CCl₄, CHCl₃, CH₂Cl₂, CH₃Cl, and the like. Suitable examples of the carbon containing gas include methane (CH₄), ethane (C₂H₆), ethylene (C₂H₄), and the like.

A showerhead assembly 230 is coupled to an interior surface 214 of the lid 204. The showerhead assembly 230 includes a plurality of apertures that allow the gases flowing through the showerhead assembly 230 from the inlet ports 232′, 232″ into the interior volume 206 of the processing chamber 200 in a predefined distribution across the surface of the substrate 100 being processed in the processing chamber 200.

A remote plasma source 277 may be optionally coupled to the gas panel 258 to facilitate dissociating gas mixture from a remote plasma prior to entering into the interior volume 206 for processing. A RF source power 243 is coupled through a matching network 241 to the showerhead assembly 230. The RF source power 243 typically is capable of producing up to about 3000 W at a tunable frequency in a range from about 50 kHz to about 200 MHz.

The showerhead assembly 230 additionally includes a region transmissive to an optical metrology signal. The optically transmissive region or passage 238 is suitable for allowing the optical monitoring system 240 to view the interior volume 206 and/or the substrate 100 positioned on the substrate support pedestal assembly 248. The passage 238 may be a material, an aperture or plurality of apertures formed or disposed in the showerhead assembly 230 that is substantially transmissive to the wavelengths of energy generated by, and reflected back to, the optical monitoring system 240. In one embodiment, the passage 238 includes a window 242 to prevent gas leakage through the passage 238. The window 242 may be a sapphire plate, quartz plate or other suitable material. The window 242 may alternatively be disposed in the lid 204.

In one implementation, the showerhead assembly 230 is configured with a plurality of zones that allow for separate control of gas flowing into the interior volume 206 of the processing chamber 200. In the example illustrated in FIG. 2, the showerhead assembly 230 as an inner zone 234 and an outer zone 236 that are separately coupled to the gas panel 258 through separate inlet ports 232′, 232″.

The substrate support pedestal assembly 248 is disposed in the interior volume 206 of the processing chamber 200 below the gas distribution (showerhead) assembly 230. The substrate support pedestal assembly 248 holds the substrate 100 during processing. The substrate support pedestal assembly 248 generally includes a plurality of lift pins (not shown) disposed therethrough that are configured to lift the substrate 100 from the substrate support pedestal assembly 248 and facilitate exchange of the substrate 100 with a robot (not shown) in a conventional manner. An inner liner 218 may closely circumscribe the periphery of the substrate support pedestal assembly 248.

In one implementation, the substrate support pedestal assembly 248 includes a mounting plate 262, a base 264 and an electrostatic chuck 266. The mounting plate 262 is coupled to the bottom 210 of the chamber body 202 includes passages for routing utilities, such as fluids, power lines and sensor leads, among others, to the base 264 and the electrostatic chuck 166. The electrostatic chuck 266 comprises at least one clamping electrode 280 for retaining the substrate 100 below showerhead assembly 230. The electrostatic chuck 266 is driven by a chucking power source 282 to develop an electrostatic force that holds the substrate 100 to the chuck surface, as is conventionally known. Alternatively, the substrate 100 may be retained to the substrate support pedestal assembly 248 by clamping, vacuum or gravity.

At least one of the base 264 or electrostatic chuck 266 may include at least one optional embedded heater 276, at least one optional embedded isolator 274 and a plurality of conduits 268, 270 to control the lateral temperature profile of the substrate support pedestal assembly 248. The conduits 268, 270 are fluidly coupled to a fluid source 272 that circulates a temperature regulating fluid therethrough. The heater 276 is regulated by a power source 278. The conduits 268, 270 and heater 276 are utilized to control the temperature of the base 264, thereby heating and/or cooling the electrostatic chuck 266 and ultimately, the temperature profile of the substrate 100 disposed thereon. The temperature of the electrostatic chuck 266 and the base 264 may be monitored using a plurality of temperature sensors 290, 292. The electrostatic chuck 266 may further comprise a plurality of gas passages (not shown), such as grooves, that are formed in a substrate support pedestal supporting surface of the chuck 266 and fluidly coupled to a source of a heat transfer (or backside) gas, such as He. In operation, the backside gas is provided at controlled pressure into the gas passages to enhance the heat transfer between the electrostatic chuck 266 and the substrate 100.

In one implementation, the substrate support pedestal assembly 248 is configured as a cathode and includes an electrode 280 that is coupled to a plurality of RF power bias sources 284, 286. The RF bias power sources 284, 286 are coupled between the electrode 280 disposed in the substrate support pedestal assembly 248 and another electrode, such as the showerhead assembly 230 or ceiling (lid 204) of the chamber body 202. The RF bias power excites and sustains a plasma discharge formed from the gases disposed in the processing region of the chamber body 202.

In the example depicted in FIG. 2, the dual RF bias power sources 284, 286 are coupled to the electrode 280 disposed in the substrate support pedestal assembly 248 through a matching circuit 288. The signal generated by the RF bias power 284, 286 is delivered through matching circuit 188 to the substrate support pedestal assembly 248 through a single feed to ionize the gas mixture provided in the plasma processing chamber 200, thereby providing ion energy necessary for performing a deposition or other plasma enhanced process. The RF bias power sources 284, 286 are generally capable of producing an RF signal having a frequency of from about 50 kHz to about 200 MHz and a power between about 0 Watts and about 5000 Watts. An additional bias power source 289 may be coupled to the electrode 280 to control the characteristics of the plasma.

In one mode of operation, the substrate 100 is disposed on the substrate support pedestal assembly 248 in the plasma processing chamber 200. A process gas and/or gas mixture is introduced into the chamber body 202 through the showerhead assembly 230 from the gas panel 258. A vacuum pump system 228 maintains the pressure inside the chamber body 202 while removing deposition by-products.

A controller 250 is coupled to the processing chamber 200 to control operation of the processing chamber 200. The controller 250 includes a central processing unit (CPU) 252, a memory 254, and a support circuit 256 utilized to control the process sequence and regulate the gas flows from the gas panel 258. The CPU 252 may be any form of general purpose computer processor that may be used in an industrial setting. The software routines can be stored in the memory 254, such as random access memory, read only memory, floppy, or hard disk drive, or other form of digital storage. The support circuit 256 is conventionally coupled to the CPU 252 and may include cache, clock circuits, input/output systems, power supplies, and the like. Bi-directional communications between the controller 250 and the various components of the processing system 200 are handled through numerous signal cables.

FIG. 3 depicts a flow diagram of one embodiment of a method 300 that may be used to fabricate the chamber component shown in FIG. 2. FIG. 4 depicts different manufacturing stage of the chamber component depicted in FIG. 3. As mentioned above, the method 300 may readily be adapted for any suitable chamber component, including a substrate support assembly, a showerhead, a nozzle, chamber walls, chamber liner and a plasma screen, among others.

The method 300 begins at block 302 by forming a body 102 out of aluminum, as shown in FIG. 4A. In one embodiment, the body 102 is made of a metallic material, such as a base aluminum, for example 6061-T6 aluminum. Conventional aluminum components not fabricated using the method 300 described herein have unreliable quality and inconsistent surface features that may lead to the formation of cracks and crazes on the surface of the chamber component 100 after the component has been exposed to a plasma environment. As such, further processing, as described in detail below, is desirable to create a robust, plasma resistant component.

At block 304, the body 102 is then immersed into an electrolyte solution that includes at least one ammonia salt or other suitable neutral electrolyte. The electrolyte solution is an aqueous solution that contains ammonia salts having a concentration of between about 0.5 M and about 2 M. The ammonia salts utilized for forming the anodized coating layer 106 may include less H⁺ so that the electrolyte solution with the aluminum salt disposed therein may maintain a desired neutral pH level, such as between a pH value of 5 to 9, for electrochemical plating process. It is believed either overly acidic or overly basic electrolyte solution may adversely attack the structure of the resultant anodized coating layer 106 formed on the body 102, resulting in high porosity of the anodized coating layer 106 as well as poor surface finish, e.g., pits or cracks resulted in the outer surface 112. Suitable examples of aluminum salts may include inorganic or organic ammonium salts, such as ammonium borate ((NH₄)₃BO₃), ammonium adipate ((NH₄)₂C₄H₈(COO)₂), ammonium oxalate ((NH₄)₂C₂O₄)), ammonium succinate ((NH₄)₂C₂H₄(COO)₂), ammonium tartrate ((NH₄)₂C₂H₂(OH)₂(COO)₂), and combinations thereof. In one particularly example, the electrolyte solution may include ammonium borate ((NH₄)₃BO₃) or ammonium adipate ((NH₄)₂C₄H₈(COO)₂).

In one example, different compounds may provide different pH levels for a given concentration, for example, the concentration/composition may include between about 0.1% and about 10% by volume of a neutral, such ammonium borate ((NH₄)₃BO₃) or ammonium adipate ((NH₄)₂C₄H₈(COO)₂) or combinations thereof, to provide the desired pH level. In one embodiment, one or more pH adjusting agents utilized to maintain a desired level of pH value in the electrolyte solution. The electrolyte solution may be provided in a tank, a sink, a bath, or any suitable container as needed.

At block 306, an electrochemical plating process is performed to form the anodized layer 106 on the outer surface 110 of the body 102, as shown in FIG. 4B. The base 102 immersed in the electrolyte solution functions as the anode. The electrolyte solution itself may function as cathodic relative to the base (anode). Alternatively, a standard hydrogen electrode, such as Ag or Pt electrodes, may be utilized as the cathode to encourage the electrochemical deposition process. One possible reduction reaction is shown in equation below.

Cathode: 6H⁺+6e⁻→3H₂

Anode: 2Al+3H₂O→Al₂O₃+6H⁺+6e⁻

Overall: 2Al+3H₂O→Al₂O₃+3H₂

A voltage potential of between 5 V and about 200 V, such as between about 15 V and about 60 V, may be utilized to drive the electrochemical deposition process. During deposition, the solution temperature may be controlled from 5 degrees Celsius to about 100 degrees Celsius, such as between room temperature and about less than about 85 degrees Celsius, for example about 25 degrees Celsius. The process time period may be between about 10 seconds and about 50 minutes. The resultant anodized layer 106 may have a thickness less than about 1 μm, such as between about 20 nm and about 300 nm.

After the electrochemical deposition process, the anodized layer 106 with desired film properties and thickness is then formed on the outer surface 110 of the base 102, forming the desired chamber component 100 with robust coating. The anodized layer 106 protects the underlying metal of the chamber component 100 from the corrosive process environment within a plasma processing chamber. The anodized layer 106 has a thickness sufficient to adequate protection from the process environment, yet is not so thick as to aggravate surface cracks and crazes. In one specific example, the anodized coating has a thickness of less than 1 μm, such as between about 20 nm and about 100 nm. More specifically, chamber parts such as pedestal, gas box, edge ring, showerhead, face plate and SMD are directly or indirectly in contact with plasma where all the reactant species such as H*, F*, O*, NO* are present. The native oxide present on the aluminum process kit is not sufficient to prevent F* radicals/ions from attacking the chamber parts containing aluminum. Conventional AlOₓ layer from traditional chemical cleaning or other types of chemical cleaning often may not be sufficient to prevent fluorine radicals/ions from reacting with aluminum surface of the chamber parts and also for reuse purpose. Thus, utilizing a dense passivation layer, as discussed herein, may provide a surface protection of the chamber parts to prevent reactive fluoride ions/radicals from reacting with aluminum from the chamber parts, thus preventing from forming AlF particles on a production substrate disposed in the processing chamber. It is believed that dense and thickness anodized passivation layer (AlOₓ) may efficiently react with fluorine ions during a plasma processing environment so that, in contrast, the surface of the anodized passivation layer may be easily saturated by the H*, O*, NO ions from the plasma so it allows all other efficient radicals to reach to the production substrate for selective etching, rather than overly attacking the chamber component.

In one embodiment, the anodized layer 106 may have a film density high than 2.7 g/cm³, such as between about 2.7 g/cm³ and 4 g/cm³, such as greater than 3.1 g/cm³. The anodized layer 106 has a pore density less than 1 percent. The anodized layer 106 may have an average pore size less than 50 nm.

The anodized layer 106 may have a surface finish (e.g., roughness) of about 16 Ra or smoother. The anodized layer 106 may have a corrosion resistance greater than 50 K-ohm. The anodized layer 106 may have a ratio of aluminum element to oxygen element of between about 1:3 and about 3:1, such as about 2:3. The anodized layer 106 may be formed amorphous or crystalline in nature. A higher voltage power may be utilized when higher ratio of crystalline nature of the anodized layer 106 is desired. Furthermore, by utilizing the method 300 of electrochemical neutral electrolyte solution, the thickness of the anodized layer may be adjusted to provide a compact, high density and robust anodized layer 106 with tunable thickness and film properties so as to accommodate different process requirement for the chamber components positioned at different locations of the processing chamber.

The method 300 for an anodized coating on a metallic body significantly improves the integrity of the over anodized coating formation process, preventing cracks and crazes from forming in the exposed surface of a chamber component. A chamber component produced by the method 300 having an anodized layer formed from a neutral electrolyte solution as described above can advantageously maintain a significantly longer exposure before penetration into the base aluminum and produces little to no physical particles. Moreover, with the anodized layer 106 formed from a neutral electrolyte solution, the characteristics of the base aluminum material with respect to intermetallics, surface defects, and internal structure become a less significant concern. As such, the anodized layer 106 formed from the neutral electrolyte solution allows the possibility for the use of porous materials for the body 102, such as cast aluminum, when fabricating chamber components for use in vacuum environments, thereby allowing an increase in manufacturing yield as these factors become less significant in meeting specifications.

With the example and explanations above, the features and spirits of the embodiments of the disclosure are described. Those skilled in the art will readily observe that numerous modifications and alterations of the device may be made while retaining the teaching of the disclosure. Accordingly, the above disclosure should be construed as limited only by the metes and bounds of the appended claims.

What is claimed is:

1. A chamber component, for use in a plasma processing apparatus, comprising:
an aluminum body having an anodized coating disposed on the aluminum body formed from a neutral electrolyte solution, wherein the anodized coating has a film density higher than 3.1 g/cm⁻².

2. The chamber component of claim 1, wherein the anodized coating is formed under the electrolyte solution with a pH value between 5 and 9.

3. The chamber component of claim 1, wherein the anodized coating has a thickness less than 1 μm.

4. The chamber component of claim 1, wherein the electrolyte solution includes at least one ammonium salt or neutral electrolyte.

5. The chamber component of claim 4, the ammonium salt is selected from a group consisting of ammonium borate ((NH₄)₃BO₃), ammonium adipate ((NH₄)₂C₄H₈(COO)₂), ammonium oxalate ((NH₄)₂C₂O₄)), ammonium succinate ((NH₄)₂C₂H₄(COO)₂), ammonium tartrate ((NH₄)₂C₂H₂(OH)₂(COO)₂), and combinations thereof.

6. The chamber component of claim 1, wherein the anodized coating has aluminum oxide layer.

7. The chamber component of claim 1, wherein the anodized coating has an average pore size less than 50 nm.

8. The chamber component of claim 1, wherein the anodized coating has corrosion resistance greater than 50 K-ohm.

9. An apparatus for use in a plasma processing chamber having a substrate pedestal adapted to support a substrate, comprising:
a chamber component having an aluminum body with an anodized coating disposed on the aluminum body formed from a neutral electrolyte solution, wherein the anodized coating has a surface roughness less than 16 Ra.

10. The apparatus of claim 9, wherein anodized coating of the chamber component has corrosion resistance greater than 50 K-ohm.

11. The apparatus of claim 9, wherein anodized coating of the chamber component has a thickness less than 1 μm.

12. A method for fabricating a chamber component for use in a plasma processing environment, comprising:
immersing a body of the chamber component from aluminum into an electrolyte solution including at least one ammonium salt;
controlling a pH level of the electrolyte solution around neutral;
applying a voltage to the electrolyte solution; and
forming an anodizing coating on the body.

13. The method of claim 12, wherein the pH value of the electrolyte solution is between about 5 and about 9.

14. The method of claim 12, wherein the ammonium salt in the electrolyte solution has a concentration between about 0.5 M and about 2 M.

15. The method of claim 12, the ammonium salt is selected from a group consisting of ammonium borate ((NH₄)₃BO₃), ammonium adipate ((NH₄)₂C₄H₈(COO)₂), ammonium oxalate ((NH₄)₂C₂O₄)), ammonium succinate ((NH₄)₂C₂H₄(COO)₂), ammonium tartrate ((NH₄)₂C₂H₂(OH)₂(COO)₂), and combinations thereof.

16. The method of claim 12, wherein applying the voltage further comprises:
applying a voltage of between 5 Volts and about 200 Voltages to the electrolyte solution.

17. The method of claim 12, further comprising:
maintaining a solution temperature of less than 85 degrees Celsius.

18. The method of claim 12, wherein the anodizing coating has a surface finish of 16 Ra or smoother.

19. The method of claim 12, wherein the anodizing coating has an average pore size less than 50 nm.

20. The method of claim 12, wherein the anodizing coating has a thickness less than 1 μm.
